(19) United States
(12) Patent Application Publication
(10) Pub. No.: US 2019/0385841 A1
(43) Pub. Date: Dec. 19, 2019

(54) HfO2 Devices

(71) Applicant: University of Exeter, Exeter (GB)

(72) Inventors: Freddie Withers, Devon (GB); Saverio Russo, Devon (GB); Monica Craciun, Devon (GB); Matt Barnes, Delft (NL); Adolfo de Sanctis, Devon (GB); Namphung Peimyoo, Devon (GB)

(21) Appl. No.: 16/261,282

(22) Filed: Jan. 29, 2019

(30) Foreign Application Priority Data
Jun. 14, 2018 (GB) 1809757.6

(51) Int. Cl. H01L 21/02

(52) U.S. Cl. CPC H01L 21/02244; H01L 21/02181; H01L 21/02175; H01L 21/02189; H01L 21/02192; H01L 21/02183

(57) ABSTRACT

The present invention relates to a method for the manufacture of a device, such as a van der Waals heterostructure device, comprising a layer of an oxide of hafnium, tantalum, zirconium, niobium, tin or rhenium, and to a device comprising the same.

### CROSS REFERENCE TO RELATED APPLICATIONS

This application claims the benefit of Great Britain Application No. 1809757.6, filed Jun. 14, 2018, which is incorporated herein by reference in its entirety.

### FIELD

The present invention relates to a method for the manufacture of a device, the method comprising laser irradiation of a layer of HfS₂ in order to oxidize it, and to a device comprising the same.

### BACKGROUND

Semiconductor devices have been known for some time. The high quality of native oxide which can be grown on the surface of silicon has underpinned the wide success of modern microelectronics. This oxide dielectric naturally allowed for metal-oxide-semiconductor field-effect transistor (MOSFET) device architectures and enabled the creation of a multi-trillion-dollar semiconductor industry. In recent years, high-k dielectrics such as hafnium dioxide, HfO₂, have been adopted in order to reduce the dimensions of microelectronic components and boost their performance. Recent work has shown similar native oxides in two-dimensional (2D) materials HfSe₂ and ZrSe₂. More recently, improvements in the scaling down of conventional semiconductor devices have been facilitated by incorporating high-k dielectric materials such as HfO₂.

Van der Waals (vdW) heterostructure devices based on 2D materials have also been known for some time. 2D materials, which are also sometimes referred to as single layer materials, are crystalline materials consisting of a single layer of atoms. Their properties make them useful in applications such as semiconductors, photovoltaics, electrodes and water purification. Layered combinations of different 2D materials are generally called van der Waals heterostructures.

In comparison to silicon, vdW heterostructure devices are likely to play an important role in future electronic device applications. With a rapidly growing family of layered 2D materials, the multitude of possible heterostructure combinations available will allow for device designs with unprecedented functionalities and improved performance. To date, many such vdW heterostructure devices have been demonstrated, such as vertical tunnelling transistors with negative differential resistance, light emitting quantum wells, photovoltaic and memory devices.

Contrary to the conventional molecular beam epitaxy (MBE) growth of semiconductor devices, vdW heterostructures make it possible to produce atomically sharp interfaces between different materials (i.e. semiconductors, insulators, semimetals, etc.) without concerns for their inter-compatibility during fabrication. Most significantly, the absence of dangling bonds on the surface of atomically thin materials allows for the creation of atomically sharp interfaces, eliminating the problem of inter-diffusion, which is known to impose severe limitations on the down-scaling of devices fabricated by standard semiconductors.

The technological progress of flexible vdW heterostructure devices based on 2D materials will also require a similar step forward in the down-scaling of devices, and in the reduction of the drive voltages to less than about 1 V. Presently, state-of-the-art flexible vdW heterostructures rely on high purity hexagonal boron nitride (hBN) as a gate dielectric, a tunnel barrier or as a high-quality substrate material. However, high-quality hBN crystals are not widespread, and scalable chemical vapour deposition (CVD) versions typically contain impurities which lead to significant leakage current in transistor devices. Furthermore, the dielectric constant of hBN (k≅4) is comparable to that of SiO₂ (k=3.9), thus preventing suitable scaling in vdW nano-electronics.

The dielectric constant k of about 4 for hBN is more than four times smaller than that of HfO₂. However, conventional deposition methods for the growth of high-k dielectrics, such as HfO₂, are known to degrade the electrical properties of atomically thin systems. There have therefore been problems to date with methods of depositing materials having a high dielectric constant on vdW heterostructures.

Common deposition techniques such as sputtering and atomic-layer deposition (ALD), used for SiO₂ and HfO₂ in semiconductor devices, are not compatible with 2D materials due to the resulting surface roughness or the lack of surface dangling bonds, which give poor interface quality in the subsequent multi-layer vdW heterostructures. These methods are also found to damage the underlying 2D crystal. Mleczko et al (Sci. Adv, 2017; 3; e1700481) describe the possibility of forming native HfO₂ and ZrO₂ high-k dielectrics from layered diselenides HfSe₂ and ZrSe₂; however, it does this by exfoliating layers of ZrSe₂ and HfSe₂ onto silicon in an inert environment, then leaving it open and exposed to open laboratory air for variable time intervals (of several days), to allow the selenides to oxidise over longer periods of time.

Chamlagain et al (2D Mater. 4 (2017); 031002) describe the conversion of multilayer TaS₂ flakes to Ta₂O₅ with a high dielectric constant of ˜15.5, via a thermal oxidation process, i.e. by heating on a hot plate at 300° C. for 3 hours in air.

However, these two methods have their own drawbacks. Thermal oxidation is a slow process, cannot be patterned, and has greater surface roughness. Natural oxidation is a very slow process, and the resultant oxide surface is not compatible with layer by layer engineering, i.e. stacking additional 2D material flakes. Unless the surface is atomically flat, subsequently transferred flakes will not adhere well.

Therefore, the search for alternative dielectrics or novel technologies, compatible with 2D materials and with high-k, is important and timely.

There is therefore a need for a method of manufacturing such devices with materials having high dielectric constants, such as HfO₂, deposited thereon, which does not result in these drawbacks.

### SUMMARY

Therefore, in accordance with the present invention, there is provided a method of manufacturing a device, the method comprising oxidizing a layer of a disulphide or diselenide of hafnium, tantalum, zirconium, niobium, tin or rhenium, the layer having been deposited on a substrate, wherein oxidation is carried out using laser irradiation.

According to one embodiment of the invention, the metal used is hafnium.

According to another embodiment of the invention, the metal used is hafnium disulphide, HfS₂.

For convenience only, the details of the present invention will be explained with reference to HfS₂ as the subject material which is exposed to the laser irradiation. However, this is intended to be purely exemplary, and is in no way intended to be limiting upon the scope of the invention. The invention is also intended to be directed to the disulphides or diselenides of the other metals named hereinabove.

According to one embodiment, the device may be a van der Waal's heterostructure, which may form part of a semiconductor, a transistor, a quantum well, a photovoltaic device, or a memory device.

The laser irradiation may be of any wavelength suitable to achieve a rapid—potentially within 1 or 2 minutes for a 6″ wafer of HfS₂-oxidation of the HfS₂, and also be of a value which is less than that required to ablate the HfS₂ from the substrate. Different wavelengths ranging from about 250 nm to about 1050 nm, or 275 nm to about 1024 nm, could be used. Incoherent sources of light may also be employed.

For example, light which is in the UV or visible ranges of the electromagnetic spectrum may be used. If the light is in the UV range of the electromagnetic spectrum, it is typically in the range of 300-400 nm, more typically 325-390 nm, more typically 350-380 nm. If the light is in the visible range of the electromagnetic spectrum, it is typically in the range of 400-550 nm, more typically 425-525 nm, more typically 450-500 nm, more typically 460-480 nm. By way of non-limiting examples, wavelengths of 375 nm and 473 nm have been used.

The energy density of the laser irradiation may be any that is suitable for the oxidation process, and also be of a value which is less than that required to ablate the HfS₂ from the substrate. Typically, the energy density is in the range of 25-75 mJ/μm², more typically 35-65 mJ/μm², more typically 50-60 mJ/μm². By way of a non-limiting example, an energy density of 53 mJ/μm² has been used.

The method of the present invention enables the incorporation or embedding of an ultra-thin high-k dielectric material, such as HfOₓ material (the HfOₓ denotation is used to indicate amorphous form from elemental analysis. The value of x=about 2; however, there is no long-range order, so the stoichiometry of the material is not exact) within vdW heterostructures through photo-oxidation of the 2D semiconductor HfS₂ via laser irradiation. The resultant oxide is found to have a dielectric constant k of about 15. This hafnium oxide can be selectively written even when the HfS₂ is embedded within complex multi-layer vdW heterostructures, and under a plurality of metallic contacts. This technology can be exploited to demonstrate various vdW devices to suit various functionalities, including flexible field effect transistors (FETs), resistive switching memory elements (ReRAMs) and light emitting and ultra-fast light detecting quantum well structures. All these devices show performances equal to or superior to state-of-the-art vdW devices, with FETs displaying on/off ratios of 10⁴ and subthreshold swings of 60 mV/dec. The invention demonstrates that HfOₓ is an ideal dielectric for complex vdW heterostructure devices with simplicity and scalability intrinsic to its incorporation, removes the need for invasive sputtering or ALD methods, and allows for clean atomically flat interfaces, without damaging the underlying 2D materials, resulting in a high-quality surface for subsequent vdW heterostructure production. All the fabricated devices show performances comparable or superior to state-of-the-art vdW devices, with the quality of FETs rivalling commercial semiconductor devices.

### Photo-Oxidation of HfS₂ in vdW Heterostructures

HfS₂ is a layered semiconductor with an indirect gap of 1.2 eV in its bulk form and has an atomically smooth surface after mechanical exfoliation. Because of this, it makes a strong van der Waal's contact with other layered 2D materials such as graphene, hexagonal boron nitride and transition metal dichalcogenides (TMDCs). HfS₂ is therefore highly suitable for the formation of complex vdW heterostructures without issues, such as a significant build-up of contamination or flake scrolling caused by poor interface adhesion. This is in stark contrast to the properties of layered oxides such as BSCCO (i.e. bismuth strontium calcium copper oxide), mica or V₂O₅, which have been shown to form a poor interface with graphene owing to the surface chemistry of those oxides preventing adequate self-cleaning. At the same time, the use of atomically flat oxides such as V₂O₅ results in a significant reduction in the mobility and high level of p-type doping in graphene. However, graphene encapsulated in laser written HfOₓ shows only a factor of 2 reduction in mobility compared to graphene on hBN and only a small level of n-type doping.

The devices of the invention are typically fabricated by micro-mechanical exfoliation of bulk crystals, and heterostructures are produced by dry transfer methods. After heterostructure fabrication, electrodes are patterned using electron beam or optical lithography, followed by metallization with Cr/Au contacts. Once fabricated, the HfS₂ is then selectively oxidized using a laser irradiation, which, for example, may have a wavelength of about 473 nm and an energy density of about 53 mJ/mm².

According to a further aspect of the invention, there is also provided a device comprising a layer of an oxide of hafnium, tantalum, zirconium, niobium, tin or rhenium which has been produced via laser irradiation of a disulphide or diselenide of hafnium, tantalum, zirconium, niobium, tin or rhenium which has previously been deposited on a substrate, according to the method as defined hereinabove.

### BRIEF DESCRIPTION OF THE DRAWINGS

The invention will now be described further by way of example with reference to the following Figures which are intended to be illustrative only and in no way limiting upon the scope of the invention.

FIGS. 1A, 1B, 1C and 1D show the processing route of the vdW heterostructure processing route.

FIGS. 2A and 2B show a breakdown of HfOₓ dielectrics.

FIGS. 3A, 3B, 3C and 3D show HfOₓ as an electrical contact material and gate oxide in a dual gated graphene FET.

FIGS. 4A, 4B, 4C, 4D, 4E, and 4F show transition metal dichalcogenide (TMDC) field effect transistors using photo-oxidised HfS₂.

FIGS. 5A, 5B, 5C, and 5D show an example of a resistive switching memory element (ReRAM).

FIGS. 6A, 6B, 6C, 6D, 6E, and 6F show thin HfOₓ barriers for optoelectronic applications.

### DETAILED DESCRIPTION

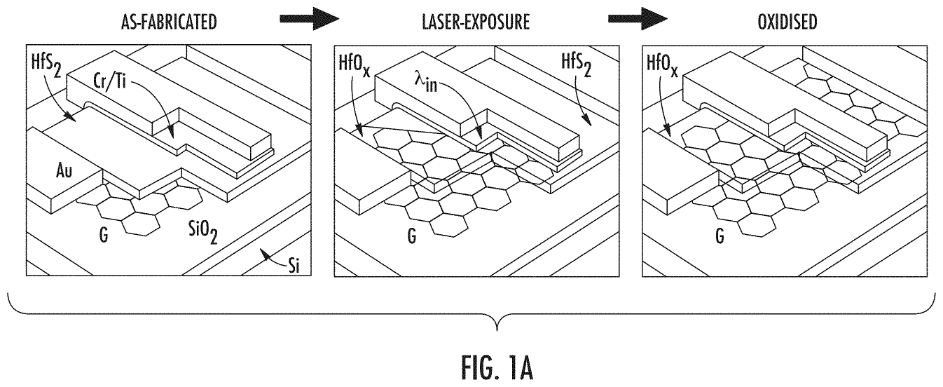

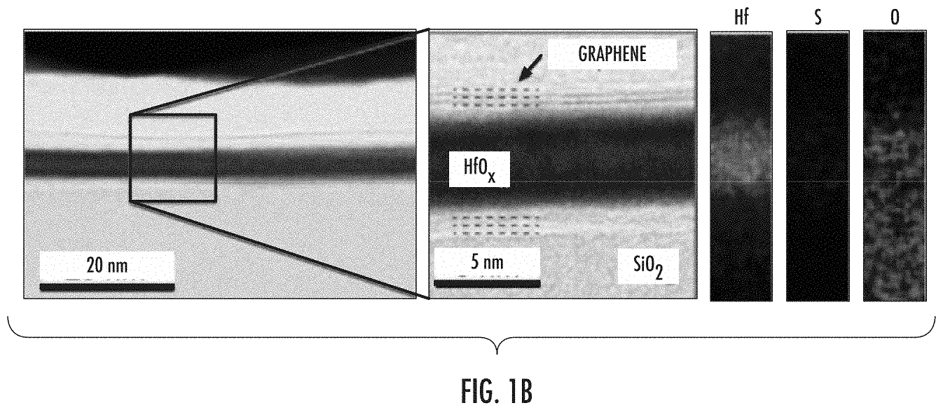

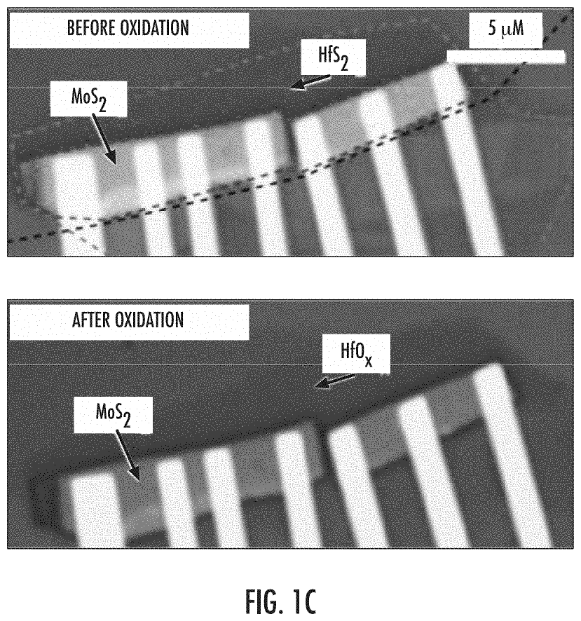

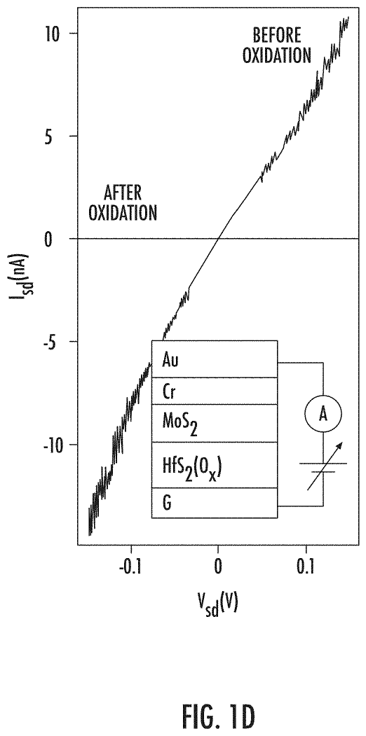

The procedure used to fabricate the devices of the invention is illustrated in FIG. 1A. FIG. 1A shows a schematic of a simple top gated graphene FET and the transformative laser oxidation process. A layer of graphene is applied to a Si/SiO₂ bottom layer, and the layer of HfS₂ is applied on top of the graphene. Heterostructures are assembled using dry transfer of micro-mechanically exfoliated 2D crystals, involving peeling from a polydimethylsiloxane (PDMS) membrane. A layer of ultra-thin HfS₂ is placed in the stack where the dielectric is required (FIG. 1A, left).

In more complex structures, additional layers are subsequently transferred. Once the device has been produced and the contacts defined by electron-beam lithography, the desired region of oxide is selectively irradiated using visible laser light (FIG. 1A, centre and right, see Methods, below). It has been shown that upon laser irradiation, thin HfS₂ undergoes an oxidation reaction due to the charge transfer between the semiconductor and the water redox couple present on its surface, and it converts into an oxide of hafnium. The oxidation takes place even under the thick (˜70 nm) Au contacts. The dielectric response of this material and its potential for down-scaling of vdW electronics have never previously been explored.

FIG. 1B shows a high-resolution transmission electron microscopy (HRTEM) image of the cross-section of a few layer Graphene/HfOₓ/Graphene device (left), where the graphene is still clearly visible whilst the long-range crystal order of HfS₂ is lost, and the resultant material appears in an amorphous phase. Energy dispersive X-ray spectroscopy (EDX) analysis confirms that the only species present in this phase are hafnium and oxygen, with only low levels of sulphur left after laser irradiation.

In FIG. 1C, there are optical images of a Graphene/HfS₂/MoS2 heterostructure both before (top) and after (bottom) the oxidation. The black dotted line outlines the region of the graphene back gate, the green dotted line outlines the HfO₂, and the red dotted line outlines the MoS₂.

The insulating properties of the laser-written HfOₓ were investigated by fabricating a MoS₂ field-effect transistor (FET) with an 8 nm HfS₂ flake separating a graphene gate electrode and the Cr/Au contacts, as shown in FIG. 1C. After laser exposure, the transparency of the HfS₂ film increases significantly, indicating an increase in the band-gap from 1.2 eV, consistent with the formation of an oxide (E_{g}˜5.5 eV, expected for HfOₓ). Vertical electron transport through the oxide further supports the transformation to a wide gap semiconductor and indicates that oxidation not only occurs under the flakes of 2D materials, but also under thick Au contacts (d=60 nm).

FIG. 1D shows the I_{sd}-V_{sd} (i.e. current v applied voltage) characteristics for such device. Before oxidation (the diagonal red line), the Isd-Vsd relationship shows the non-linear behaviour expected for tunnelling through a series of semiconducting materials, with a low-bias vertical resistance R˜20×10⁶ Ω μm². After oxidation (the horizontal green line), the current falls below the measurement resolution of our instrument (see Methods, below), setting the lower limit of the resistivity to be R˜10¹¹ Ω μm² extracted around Vsd=0 V. The inset shows the stacking sequence of the various different layers in the heterostructure.

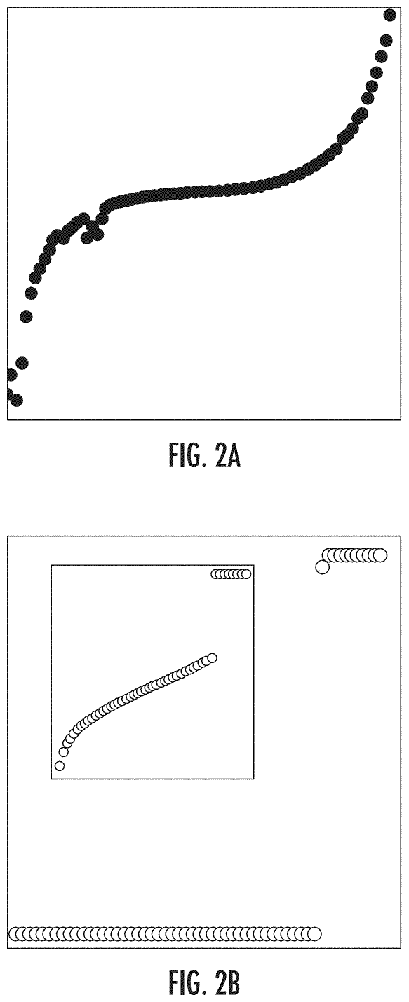

FIG. 2A shows a graph of current (I_{sd}) vs applied voltage (V_{sd}) characteristics for a 5 nm Graphite/HfOₓ—Cr/Au junction.

FIG. 2A shows a few gate sweeps at different V_{sd} biases for an 8 nm MoS₂ channel and a 6 nm HfOₓ dielectric layer. Such devices display subthreshold swings as low as 60 mV/dec. The breakdown voltage of the laser-written oxide was measured using a Graphite/HfOₓ/Cr (5 nm)/Au (60 nm) vertical electron tunnelling device, schematically shown in the inset of FIG. 2A. In such thin oxide films (d≤5 nm) a tunnelling current can be measured when a source drain bias is applied across the vertical junction, as shown.

FIG. 2B shows a graph of I_{sd} v V_{sd} for an extended voltage range showing the breakdown field for the dielectric. The inset shows the log scale plot of the same data showing the exponential dependence of tunnelling current with bias voltage.

FIG. 2B shows the same data as FIG. 2A but plotted in linear scale to highlight the small level of hysteresis (swept at 0.3 V/min). This tunnel current increases exponentially until an electric field of Ebd˜0.5-0.6 V/nm is applied, at which point the current discontinuously increases to the compliance level of the voltage source-meter, as shown in FIG. 2B. This breakdown field is comparable to that of SiO₂ and hBN 0.6-2.5 V/nm and 1 V/nm respectively.

Similar devices produced on flexible PET substrates display similar characteristics and resilience over many bending cycles to uniaxial strains of about 1.6%. Ultra-thin HfOₓ layers allow for tunnelling currents in vertical devices, as such complex vertical tunnelling devices can be produced such as light emitting and detecting quantum wells.

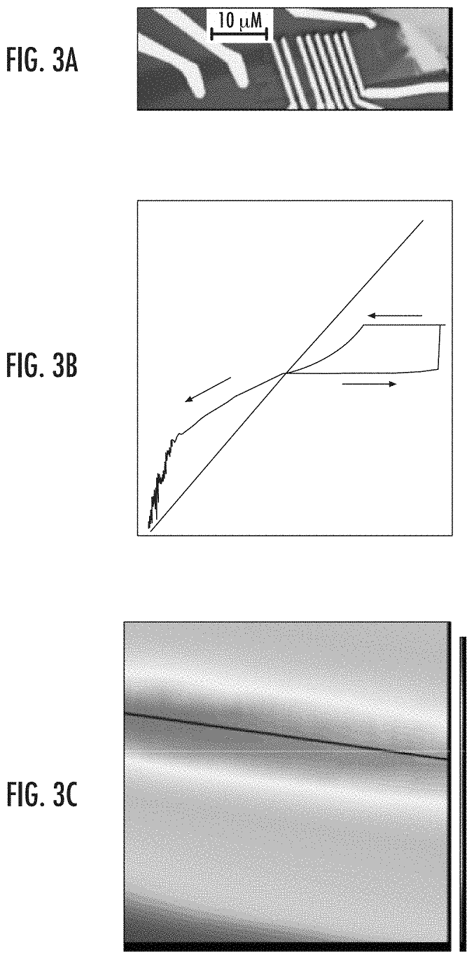

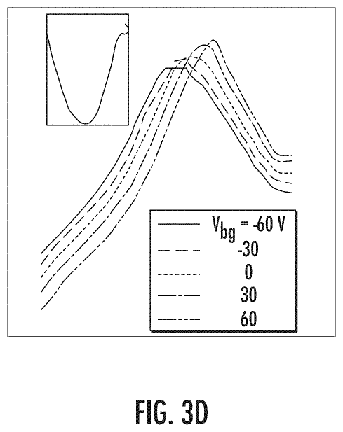

To better understand the dielectric properties of the laser-written HfOₓ, dual-gated graphene field-effect transistors (FETs) were fabricated. An optical micrograph of a FET constructed on a Si/SiO₂ (285 nm) substrate from a stack of bi-layer graphene/HfOₓ (7 nm) and Cr/Au contacts is shown in FIG. 3A.

The metal contacts are placed directly on the bilayer graphene (contacts 1, 2 and 11 in FIG. 3A) and on top of the HfOₓ (contacts 3-10 in FIG. 3A). To form a contact between the top Cr/Au metal lead and the graphene underneath the HfOₓ, there is a formation of a conductive filament after breakdown of the dielectric. In this way, for example, contacts 7,8 in FIG. 3A can be used as source and voltage probes and contacts 9,10, and 11 as drain and voltage probes, while the other metal leads (3-6 and 8) are used as top-gates.

FIG. 3B shows a graph of I_{sd} v V_{sd} indicating the formation of a conductive filament in the oxide (red curve) further sweeps reduce resistance to tens of kiloohms (see the blue and black curve).

The red curve shows the first voltage sweep which leads to the formation of the filament at a vertical electric field of ˜0.5 V/nm. Further cycling of the source-drain bias leads to stable filament formation which contacts the underlying graphene channel with typical resistances of about 10-20 kΩ Back-gate (SiO₂) sweeps of the resistance show the bilayer graphene to be heavily p-type doped with the charge neutrality point (CNP) lying at VCNP˜80 V. Such doping levels are attributed to the oxygen plasma cleaning of the Si—SiO₂ substrate, used to promote the adhesion of graphene during exfoliation. Similar hBN-Graphene-HfOₓ stacks show negligible doping compared to graphene on hBN.

FIG. 3C shows a four-terminal top gate-back gate contour plot of the 4-point channel resistance between contacts 7 and 9 (contacted through filamentation) with contact 8 serving as the top gate electrode. From the slope of the neutrality point, dV_{tg}/dV_{bg}, and the thickness of the oxide, the dielectric constant of the HfOₓ material is calculated to be k˜15. This value is comparable to literature values for amorphous HfOₓ.

FIG. 3D shows a graph of R(Vtg) for different values of Vbg from ˜60V to +60V; the inset shows the gate-channel tunnel current density. The analysis of several top gate (Vtg) sweeps, as shown in FIG. 3D, reveals a gate leakage current density (see inset) similar in magnitude to literature values for amorphous HfOₓ films of comparable thickness. This therefore confirms that the dielectric properties of the laser-written HfOₓ are comparable to those of sputtered HfOₓ films, and are thus suitable for implementation in electronic devices.

### Laser-Written HfOₓ as a High-k Dielectric for 2D Field-Effect Transistors

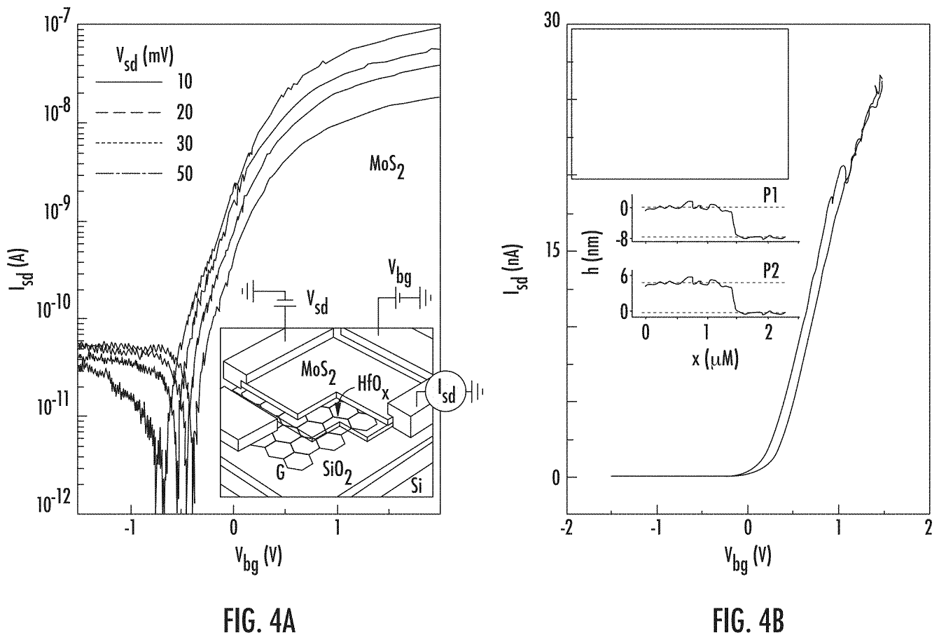

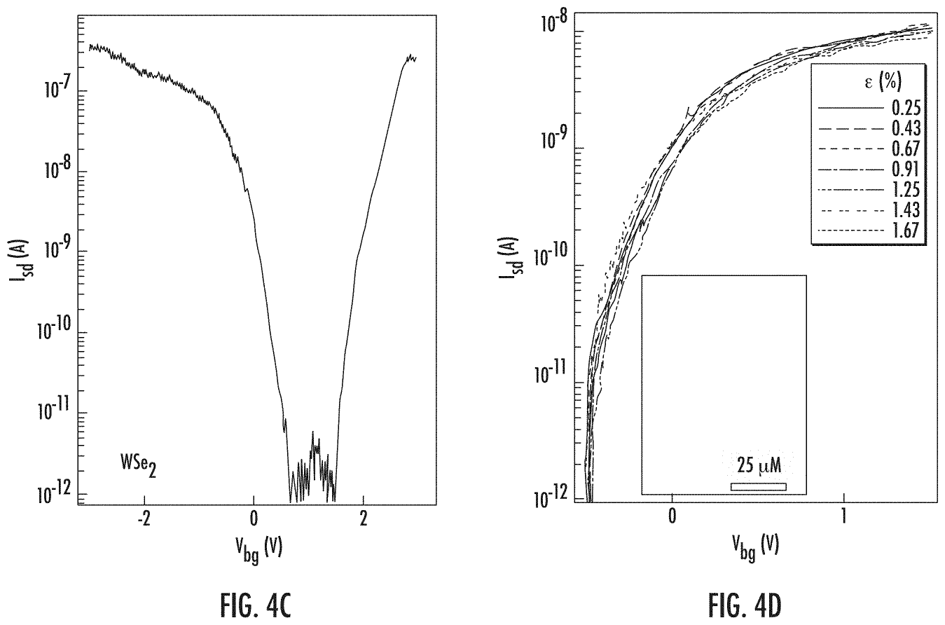

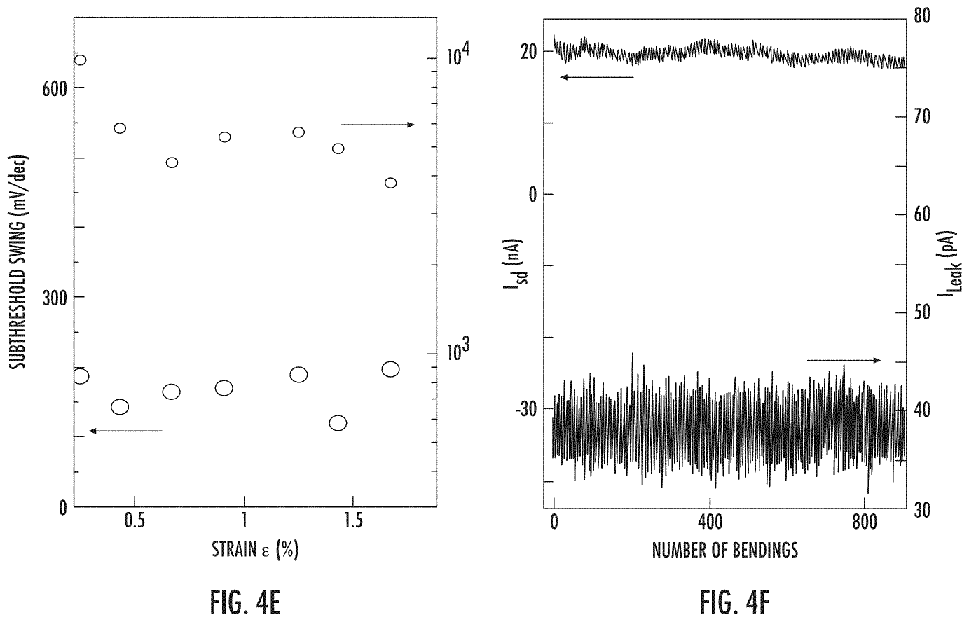

In FIG. 4A, there is a graph of Isd-Vg for a MoS₂ FET; an 8 nm oxidised HfS₂ film is schematically shown in the inset.

FIG. 4B depicts the same data as in FIG. 4A, but plotted in a linear scale to highlight small hysteresis when reversing the sweep direction. The inset shows the AFM image for the device along with the height profile for the HfOₓ (P1) and the MoS₂ (P2).

In FIG. 4C, the field effect properties of a WSe₂ FET showing ambipolar field effect behaviour is shown.

In FIG. 4D, the field effect properties of a MoS₂FET on 0.5 mm PET substrate for different levels of strain up to 1.6% at Vsd=10 mV is shown.

In FIG. 4E, a subthreshold swing and Ion/Ioff ratio for the same device as in FIG. 4D is shown.

In FIG. 4F, source-drain current at Vsd=20 mV (blue) and gate leakage current (red) at Vgs=1.5 V or over 800 bending cycles are shown.

A drawback of graphene FETs is the absence of a band gap which prevents the use of this single layer of carbon atoms in practical field effect transistors, where a suitable Iₒₙ/I_{off} ratio is required. In contrast, few-layer transition metals dichalcogenide (TMDC) are semiconductors and yet atomically thin, therefore ideally suited for FET applications. As such, these materials are likely to play an important role in future bendable electronic and optoelectronic applications. Therefore, the fabrication of TMDC-FETs using ultra-thin high-k HfOₓ on Si/SiO₂ and flexible PET substrates was explored.

The performance of such devices on a rigid Si/SiO₂ substrate, as schematically illustrated in the inset of FIG. 4A, was studied. Applying a voltage to the graphene electrode (V_{bg}) allows for the modulation of the carrier density of the MoS₂ channel The two-terminal gate dependence of the source-drain channel current (I_{sd}) for a few-layer MoS₂ FET at different source-drain bias voltages (V_{sd}) is shown in FIGS. 4A and 4B. Such devices have turn-on voltages Vg˜−0.4 V with Iₒₙ/I_{off}>10⁴ and subthreshold swings as low as 60 mV/dec. This value corresponds to the fundamental thermionic limit of the subthreshold slope of a state-of-the-art metal-oxide-semiconductor FET. Negligible levels of hysteresis are observed in the device of the invention, as shown in FIG. 4B, for a sweep rate 0.3V/min and V_{b}=10 mV. Hysteresis is typically seen for TMDC FETs on SiO₂ substrates due to the presence of water and oxygen, which act as electric field dependent dopants. Field-effect mobilities in the linear region for the MoS₂ FETs are found to be μ˜1-2 cm²V⁻¹s⁻¹, comparable to MoS₂ FETs on SiO₂ with Au contacts. The absence of significant hysteresis highlights the high quality and low impurity content of the dielectric.

An ambipolar field-effect by using few-layer WSe₂ as the channel material is also demonstrated, as shown in FIG. 4C, where the Fermi level can be swept from conduction to valence band due to the smaller band-gap and lower doping in WSe₂.

To test the suitability of our HfOₓ for flexible applications, a multi-layer MoS₂ FET on a 0.5 mm thick PET substrate was prepared and subjected to uniaxial strains of up to 1.6% in a custom-made bending rig. The I_{sd}-V_{g} sweeps are shown in FIG. 4D, where no significant change in the device performance is observed after applying increasing levels of strain. In more detail, the subthreshold swing and Iₒₙ/I_{off} ratios are shown in FIG. 4E, as a function of applied strain. The devices of the invention operate over many bending cycles without degradation as shown in FIG. 4F, with a gate leakage current at Vg=1.5 V less than 40 pA and a small variation in the I_{sd}-V_{sd} at a bias voltage of V_{sd}=20 mV.

### Resistive Switching Memory Devices

The formation of conducting filaments illustrated in FIGS. 2A and 2B2 allow for switching between two resistance states, creating a device known as resistive switching random access memory element (ReRAM). ReRAM devices represent a promising emerging memory technology with several advantages over conventional technologies including increased speed, endurance and device density. Of several groups of materials that show resistive switching, transition metal oxides including HfOₓ are promising candidates. More recently, such devices based on two-dimensional materials are beginning to attract attention owing to high mechanical flexibility, reduced power consumption and potential for high density memory devices based on stacks of vdW heterostructures.

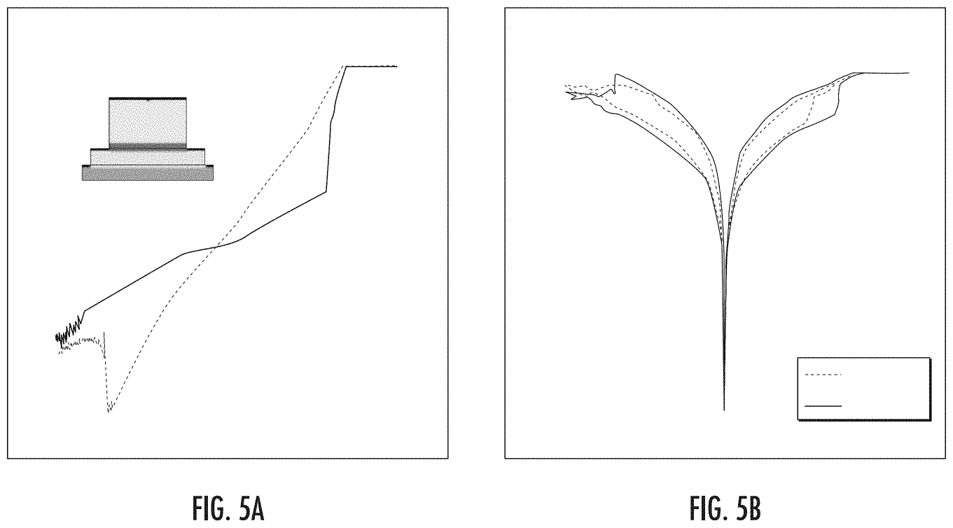

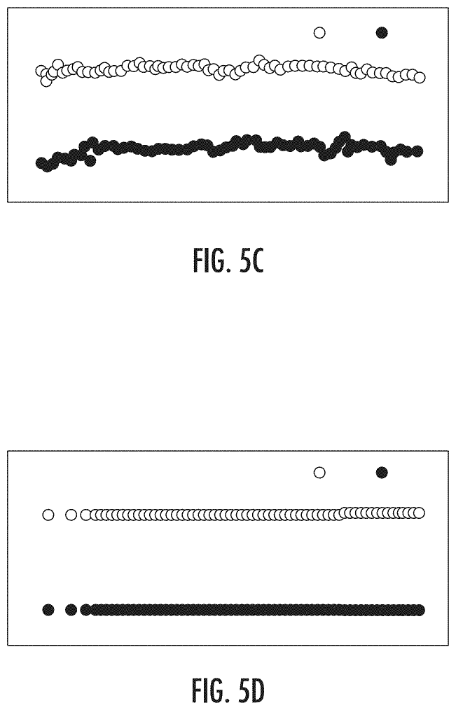

In FIG. 5A, there is depicted an example of a switching cycle for the device architecture shown in the inset in the Figure.

In FIG. 5B, there is depicted the 1^{st} and 100^{th} switching cycles for the same device shown in the inset in FIG. 5A.

In FIG. 5C, there is depicted a resistance vs cycle number for the two resistance states plotted for the LRS (blue, lower line) and HRS (red, upper line).

In FIG. 5D, there is depicted the time stability for the two resistance states.

Overall, FIGS. 5A, 5B, 5C and 5D show the device characteristics of a typical resistive switching element based on photo-oxidised few-layer HfS₂. The devices consist of a gold top electrode with either titanium or chromium used as an adhesion layer, deposited on top of the HfS₂-graphite heterostructure. Following photo-oxidation of the HfS₂, the device is subjected to repeated current-voltage sweeps, where the top metal electrode is voltage biased with respect to the bottom graphite electrode, as shown in FIG. 5A. During the initial voltage sweeps, the current is limited to 2 mA, which is important in achieving stable and repeatable resistance cycling. At +1 V, an abrupt increase in current is observed as the device switches from a high resistance state (HRS) to a low resistance state (LRS), known as the set process. The device maintains its LRS as the polarity is reversed and swept down to −1 V, at which a reduction in current for increasing negative voltage is observed, as the device switches back to the HRS, known as the reset process. The use of thin flakes allows for low voltage operation with the SET/RESET voltages around |Vsd|˜ 1 V. The memory window of devices measured here (R_{HRS}/R_{LRS}) varies from about 5 up to 10⁴ seconds, with the larger values observed for Au/Ti top electrodes.

FIG. 5B shows similar current-voltage behaviour for the 1^{st} and 100^{th} cycles. The results of repeated cycling are shown in FIG. 5C in which R_{HRS}/R_{LRS} (with both resistance values extracted at V_{sd}=100 mV), show little variation over 100 cycles. Finally, the long-term stability of this ReRAM device is investigated, and in FIG. 5D, it is shown that the resistance levels, measured for V_{sd}=250 mV, are consistent and well defined for over 10⁴ seconds. Resistive switching in devices utilizing graphene for both top and bottom electrodes was unreliable; without being bound by any particular theory, it is believed that electrode material asymmetry is crucial for reliable device performance Such bipolar switching is consistent with the formation and rupture of conducting filaments.

### Optoelectronic Devices

Having demonstrated the viability of using laser written HfOₓ as a flexible gate dielectric for FETs, memory elements and as a contact material, their applicability to optoelectronic devices has been investigated. Important for future device applications are optoelectronic components which can perform multi-functional tasks, such as detecting as well as emitting photons, thereby leading to the development of screens which could simultaneously record images.

Vertically stacked heterostructures of two-dimensional materials provide a framework for the creation of large-area, yet atomically thin and flexible optoelectronic devices with photodetectors and light-emitting diodes. So far only hBN tunnel barriers have been demonstrated, however other wide gap material oxides have not been explored when combined with vdW heterostructures. The use of ultra-thin HfOₓ tunnel barriers in vertical light emitting tunnelling transistor device geometries is demonstrated.

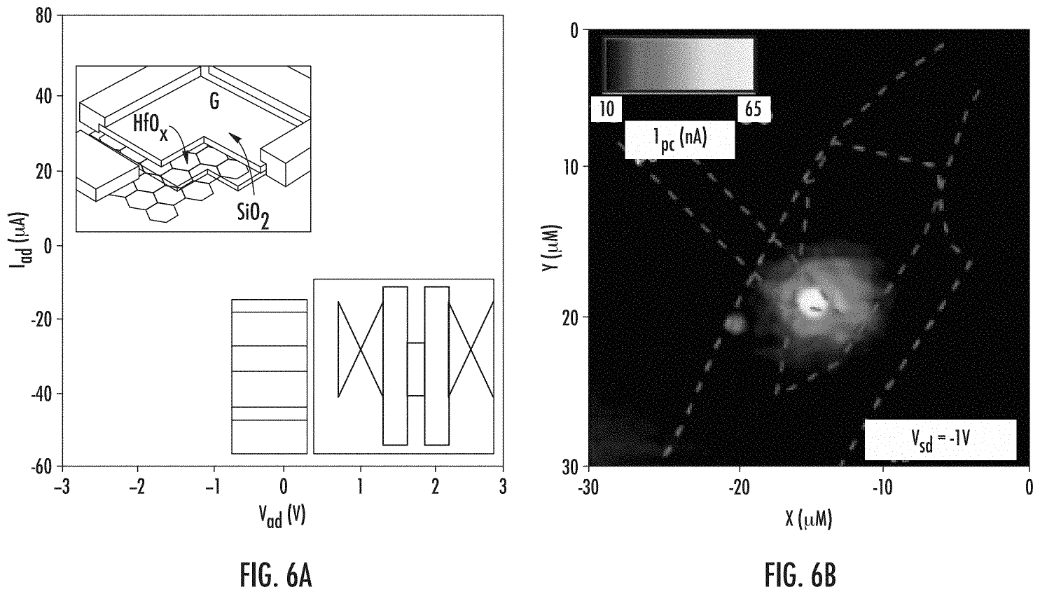

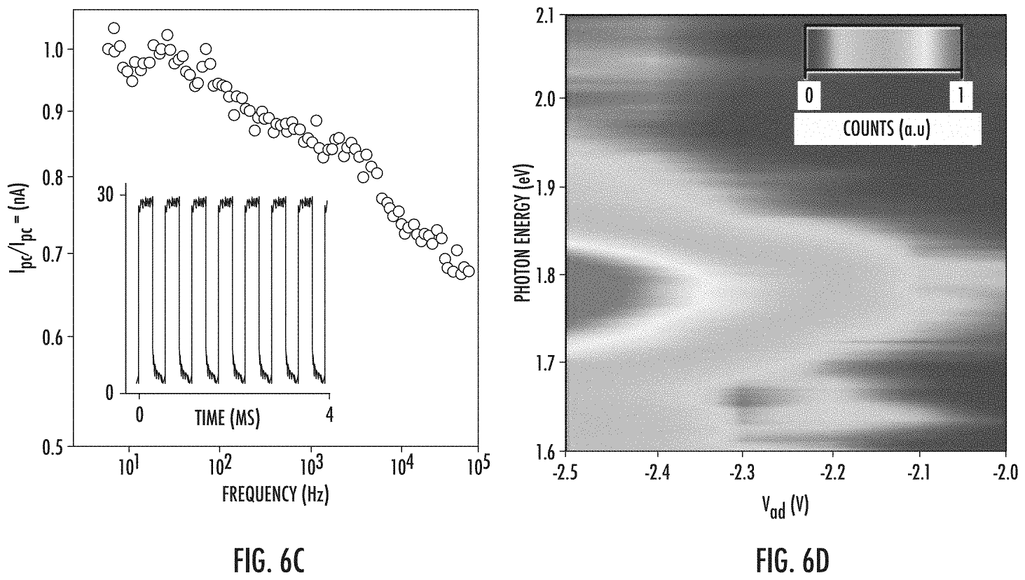

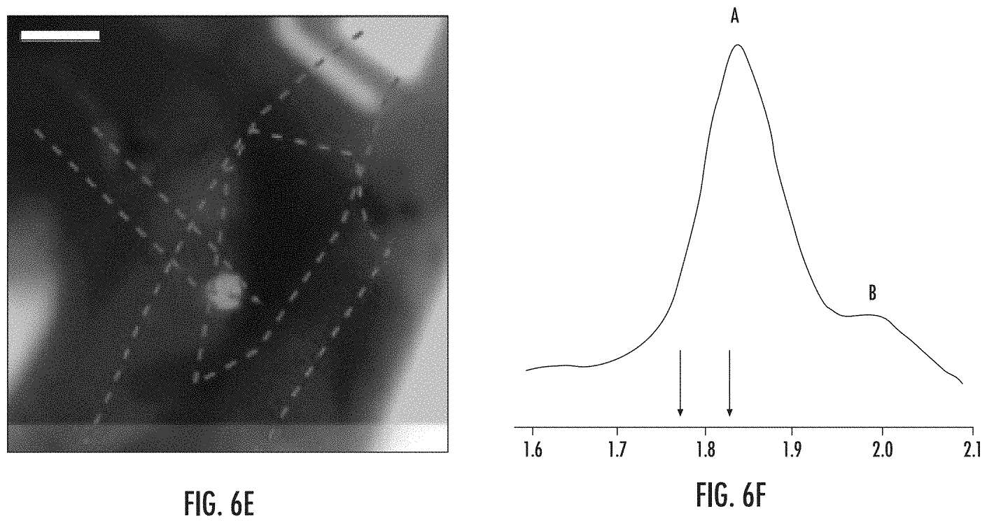

FIG. 6A shows a current-voltage curve of a HfOₓ single-quantum well device (SQW) formed by the encapsulation of MoS₂ in 2-4 nm of HfOₓ, see Methods. The lower inset is schematic of the heterostructure band-alignment (hBN-Gr_{b}-HfOₓ-MoS₂-HfOₓ-Gₜ). Applying a bias voltage between the top and bottom graphene electrodes (Gₜ and G_{b}) allows a current to tunnel through the thin HfOₓ layers and into the MoS₂ (there is a weak temperature dependence of the measured source-drain current, indicating a tunnelling mechanism rather than transport through low energy impurity states). As the bias voltage is increased from zero, the current increases non-linearly. Outside of a low-bias regime (|Vsd|>1 V), an increase in the current is observed, due to tunnelling into the conduction band of MoS₂. In addition, an asymmetry between the current at positive and negative bias voltage is observed which is likely due to both a variation in doping between Gₜ and G_{b} and a different thickness of the top and bottom HfOₓ. This behaviour is similar to previous work using hBN tunnel barriers.

To determine the active area of the heterostructure, scanning photocurrent microscopy (SPCM) is used, whereby a laser beam is rastered across the device whilst photocurrent is acquired simultaneously, see Methods. FIG. 6B shows that under a moderate bias (V_{sd}=−1 V), the photocurrent is predominately localised to regions of overlap between the top and bottom graphene flakes, each outlined in light green. Photoexcited carriers in MoS2 (red outline) are separated by the graphene electrodes due to the applied vertical electric field. Away from this region the photocurrent (I_{pc}) drops from >65 nA to <10 nA.

In FIG. 6C, a reduction is measure in the magnitude of the photocurrent as the light modulation frequency is increased. By normalising this to the value of the photocurrent at low frequencies I_{pc}⁰, it is possible to ascertain the −3 dB bandwidth of the device, which is f₋₃dB=40 kHz. From this, the rise time can be estimated using tᵣ=0.35/f_{-3dB}˜8.8 us, which is in good agreement with analysis of the temporal response of the photocurrent. The insert of FIG. 6C shows multiple iterations of the photocurrent obtained at 1.8 kHz. The measured response time is 10³-10⁶ times faster than typical planer MoS₂ photodetectors, a result arising from the use of a vertical, as opposed to lateral, contact geometry. The small electrode separation of about 6-10 nm and large electric fields of about 0.1-0.2 V/nm minimise the transit time of the photoexcited carriers. Hence, these vertical heterostructures of MoS2 encapsulated in HfOₓ are an effective high-speed light-detection architecture.

As the bias voltage is further increased, the quasi fermi-levels of the graphene electrodes allow for simultaneous injection of electrons into the conduction band of MoS₂ and holes into the valence band. The carrier confinement set by the HfOₓ tunnel barriers allows for exciton formation in the MoS₂. The subsequent decay of those excitons leads to light emission at the excitonic gap of MoS₂.

FIG. 6D shows the electroluminescence (EL) intensity map as a function of photon energy and bias voltage, where the main EL band appears at 1.78 eV.

In brief, EL is not observed when V_{sd}>−2 V. Only upon reducing the bias voltage below −2V can the EL be detected with a more intense signal recorded by increasing |V_{sd}|. The emergence of EL at −2 V corresponds well with the single particle band-gap of mono-layer MoS₂. The negative threshold voltage can be attributed to the asymmetric device structure.

FIG. 6E shows a false-colour CCD image of the EL overlaid on a monochrome image of the device at applied bias voltage of −2.5 V. The EL is localised to the active area of the device previously identified in FIG. 6B through photo-current mapping. To further understand the emission, normalised EL and photoluminescence (PL) spectra are shown in FIG. 6F. The main PL emission peak is assigned to the A exciton seen at an energy of 1.8 eV. The energy of the main EL band redshifts from that of PL by 53 meV. Typically, the exfoliated monolayer MoS₂ is n-doped, which favours the formation of negatively-charged excitons, which have a lower emission energy than that of the neutral exciton by about 30 meV.

Therefore, the main feature in electroluminescence spectra at 1.78 eV is due to the radiative recombination of the charged exciton. Moreover, the dissociation energy (i.e. energy shift referring that of the neutral exciton) of the charged exciton is proportional to the doping concentration. Therefore, the large energy difference between electroluminescence and photoluminescence is an indication of high doping in monolayer MoS₂, which is due to doping of the as-exfoliated natural MoS₂ fakes and extra charge transfer from HfOₓ. Indeed, the MoS₂ FETs shown in FIGS. 5A, 5B, 5C, and 5D display n-type behaviour supporting this.

### Methods

### Devices Fabrication

The devices of the invention were fabricated using standard mechanical exfoliation of bulk crystals and dry transfer methods utilised to form the hetero structures.

One manufacturing technique used is a PDMS stamp transfer technique. A typical fabrication route for an MoS₂ FET is as follows:

Firstly, graphene is mechanically exfoliated onto a thermally oxidised silicon wafer, which had an SiO2 thickness of 290 nm. After this the HfS₂ flakes are exfoliated between two pieces of PMDS and transferred onto the graphene. Graphene or TMDC's are then transferred by PDMD onto the HfS2 layer. The HfS₂ flakes are released from the PDMS between 50-60° C. This process is then repeated for the subsequent layers of the device. After the heterostructure stack is formed, conventional electron beam lithography is used to define electrical contacts; micro-fabrication of Cr(5 nm)/Au(50 nm) contacts to the graphene/graphite back-gate and to the TMDC channel, followed by plasma etching in O₂/Ar plasma.

The same process is used for other devices such as memory devices, dual gated graphene FET's and light emitting quantum well devices.

For devices on hBN substrates, a PMMA membrane is used, and the graphene is dry peeled from the PMMA onto the hBN.

In this work the HfS₂ and WSe₂ was purchased from HQGraphene (http://www.hqgraphene.com/), whilst the MoS₂ and hBN crystals were acquired from Manchester Nanomaterials (http://mos2crystals.com/).

Following heterostructure production the contacts were structured using either optical or electron beam lithography, followed by thermal evaporation of Cr/Au (5/60 nm) electrodes.

After assembly of the vdW heterostructure, photo-oxidation of the HfS₂ layer was performed by rastering either UV (λᵢₙ=375 nm) or (λᵢₙ=473 nm) laser light focused to a diffraction-limited spot in a custom-built setup. A typical energy density of 53 mJ/μm² was used for exposures lasting 1-2 seconds per point, depending on the thickness of the HfS₂ layer. The focused spot-size was dₛ=264 nm for the UV laser and dₛ=445 nm for the visible wavelength.

### Materials Characterisation

The materials employed in the present invention were characterised using scanning transmission-electron microscope (STEM) imaging. A cross sectional specimen for high-resolution scanning transmission-electron microscopy (HR STEM) was prepared in a FEI Dual Beam Nova 600i instrument incorporating a focused ion beam (FIB) and a scanning electron microscope (SEM) in the same chamber. Using 30 kV ion milling, platinum deposition and lift-out with a micromanipulator, a thin cross section of material was secured on an Omniprobe TEM grid and thinned down to electron transparency with low energy ions. HR STEM images were acquired using a probe side aberration-corrected FEI Titan G2 80-200 kV with an X-FEG (extreme field emission gun) electron source. Bright-field (BF) and high angle annular dark-field (HAADF) imaging were performed using a probe convergence angle of 21 mrad, a high-angle annular dark-field imaging (HAADF) inner angle of 48 mrad and a probe current of about 80 pA. The lamellae were aligned with the basal planes parallel to the incident electron probe. Correct identification of each atomic layer within bright-field and HAADF images was achieved by elemental analysis with energy dispersive X-ray (EDX) spectrum imaging.

The FEI Dual Beam Nova 600i is also fitted with a gas-injection system to allow local material deposition and material-specific preferential milling to be performed by introducing reactive gases in the vicinity of the electron or ion probe. The electron column delivers the imaging abilities of the SEM and is at the same time less destructive than FIB imaging. SEM imaging of the device prior to milling allows one to identify an area suitable for side view imaging. After sputtering of a 10 nm carbon coating and then a 50 nm Au—Pd coating on the whole surface ex-situ, the Au/Ti contacts on graphene were still visible as raised regions in the secondary electron image. These were used to correctly position and deposit a Pt strap layer on the surface at a chosen location, increasing the metallic layer above the device to about 2 μm. The Pt deposition was initially done with the electron beam at 5 kV e and 1 nA up to about 0.5 μm in order to reduce beam damage and subsequently with the ion beam at 30 kV Ga+ and 100 pA to build up the final 2 μm thick deposition. The strap protects the region of interest during milling as well as providing mechanical stability to the cross-sectional slice after its removal. Trenches were milled around the strap by using a 30 kV Ga+ beam with a current of 1-6 nA, which resulted in a slice of about 1 μm thick. Before removing the final edge supporting the milled slice and milling beneath it to free from the substrate, one end of the Pt strap slice was welded to a nanomanipulator needle using further Pt deposition. The cross-sectional slice with typical dimensions of 1 μm×5 μm×10 μm could then be extracted and transferred to an Omniprobe copper half grid as required for TEM. The slice was then welded onto the grid using Pt deposition so that it could be safely separated from the nanomanipulator by FIB milling. The lamella was further thinned so to become partially transparent to electron beam using a 30 kV Ga+ beam and 0.1-1 nA. A final gentle polish with Ga+ ions (at 5 kV and 50 pA) was used to remove side damage and reduce the specimen thickness to 20-70 nm. The fact that the cross-sectional slice was precisely extracted from the chosen spot was confirmed for all devices by comparing the positions of identifiable features such as Au contacts and/or hydrocarbon bubbles, which are visible both in the SEM images of the original device and within TEM images of the prepared cross section.

Atomic force microscopy was performed using a Bruker Innova system operating in the tapping mode, to ensure minimal damage to the surface of the samples. The tips used were Nanosensors PPP-NCHR, which have a radius of curvature smaller than 10 nm and operate in a nominal frequency of 330 kHz.

### Electrical Measurements

I_{sd}-V_{sd} values were collected using a Kiethley 2400 voltage/current source meter. Electrical characterisation of graphene and TMDC FET's were performed using standard low noise AC Lock-in techniques using a signal recovery 7225 lock-in amplifier and a Kiethley 2400 source-meter providing the gate voltage.

All electron transport measurements were performed in either a vacuum of 10⁻³ mbar or a dry Helium atmosphere at room temperature unless otherwise stated. The flexible MoS₂ FET produced on PET was measured in ambient conditions.

The temperature dependence of the tunnelling current through a graphene-HfOₓ-Au heterostructure was checked, and it was shown that there is only a small change in the current as the temperature is reduced from T=300 K to T=4.2 K, which indicates a tunnelling mechanism for the transport through the oxide.

Back-gate sweeps of the resistance for graphene encased in different dielectric environments were carried out. This showed that the presence of HfOₓ does not significantly degrade the properties of graphene compared to graphene on hBN crystals.

### Optoelectronic Characterisation

Optoelectronic measurements were performed using a custom-built setup [CIT]. Photocurrent measurements were performed using a continuous-wave laser (λᵢₙ=514 nm, P=15 W/cm²) rastered on the devices to produce spatial maps of the photo-response. The electrical signal was acquired by a DL Instruments Model 1211 current amplifier connected to a Signal Recovery model 7124 digital signal processing lock-in amplifier. The frequency modulation of the lasers was 73.87 Hz.

Electroluminescence and photoluminescence measurements were performed in the same setup using a Princeton Instruments SP2500i spectrometer and PIXIS400 camera. All measurements were performed at room temperature under vacuum (P=10⁻⁵ mBar).

A Raman spectrum was recorded at 532 nm and laser power of 100 mW of the G and D-mode taken for graphene on HfOₓ after the photo-oxidation process has taken place. A negligible D-peak is seen after oxidation which indicates that graphene is not significantly damaged by the laser oxidation process.

### Conclusion

In conclusion, it is demonstrated that ultra-thin few layer HfS₂ can be incorporated into a variety of vdW heterostructures and successfully selectively transformed into an amorphous high-k oxide using laser irradiation. Contrary to sputtering or ALD, the use of photo-oxidised HfS₂ allows for clean atomically flat interfaces, without damaging the underlying 2D materials, resulting in a high-quality surface for subsequent vdW heterostructure production. It is demonstrated that the laser-written HfOₓ has a dielectric constant k-15 and a breakdown field of ˜0.5-0.6 V/nm.

These properties enable the manufacture of high-quality vdW heterostructure devices using this oxide, such as, but not limited to: (1) ReRAM memory elements which operate in the <1 V voltage limit; (2) flexible TMDC-FETs with Iₒₙ/I_{off}>10⁴, thermionic-limited subthreshold swing of 60 mV/dec, and good resilience to bending cycles; (3) optoelectronic devices based on quantum-well architectures, which can emit and detect light in the same device, with EL intensities and drive voltages comparable to devices with hBN barriers and photodetection response times up to 10⁶ times faster than equivalent planer MoS₂ devices. Moreover, the high-k dielectric constant, the compatibility with 2D materials and the ease of laser-writing techniques will allow for significant scaling improvements and greater device functionality, which we predict to be an important feature for future flexible semi-transparent van der Waals nanoelectronics.

It is of course to be understood that the present invention is not intended to be restricted to the foregoing examples which are described by way of example only.

1. A method of manufacturing a device, the method comprising oxidizing a layer of a disulphide or diselenide of hafnium, tantalum, zirconium, niobium, tin or rhenium, the layer having been deposited on a substrate, wherein oxidation is carried out using laser irradiation.

2. A method according to claim 1, wherein hafnium disulphide is employed.

3. A method according to claim 1, wherein the laser irradiation has a wavelength of between 250 and 1050 nm.

4. A method according to claim 1, wherein the laser irradiation has a wavelength of between 300 and 500 nm.

5. A method according to claim 1, wherein the energy density is in the range of 25-75 mJ/μm².

6. A method according to claim 1, wherein the device comprises a van der Waal's hetero structure.

7. A method according to claim 1, wherein the device is selected from a semiconductor, a transistor, a quantum well, a photovoltaic device or a memory device.

8. A device comprising a layer of an oxide of hafnium, tantalum, zirconium, niobium, tin or rhenium which has been produced via laser irradiation of a disulphide or diselenide of hafnium, tantalum, zirconium, niobium, tin or rhenium, according to the method of claim 1.

9. A device according to claim 8, wherein the device is selected from a semiconductor, a transistor, a quantum well, a photovoltaic device or a memory device.
